(19) United States
(12) Patent Application Publication
(10) Pub. No.: US 2012/0217654 A1
(43) Pub. Date: Aug. 30, 2012

(54) SEMICONDUCTOR DEVICE AND METHOD FOR FABRICATING THE SAME

(76) Inventors: Sang-Hoon SHIN, Gyeonggi-do (KR); Kwan-Weon Kim, Gyeonggi-do (KR)

(21) Appl. No.: 13/292,609

(22) Filed: Nov. 9, 2011

(30) Foreign Application Priority Data
Feb. 28, 2011 (KR) 10-2011-0017700

(51) Int. Cl. H01L 27/10; H01L 21/78; H01L 21/50

(52) U.S. Cl. 257/777; 438/107; 438/113; 257/E27.07; 257/E21.499; 257/E21.599

(57) ABSTRACT

A semiconductor device includes a wafer comprising a chip that passes a test and a chip that does not pass a test, one or more first stacked chips that are stacked over the chip that passes a test, and one or more second stacked chips that are stacked over the chip that does not pass a test, wherein the second stacked chips comprise at least one between an chip that does not pass a test and a dummy chip.

### CROSS-REFERENCE TO RELATED APPLICATIONS

The present application claims priority of Korean Patent Application No. 10-2011-0017700, filed on Feb. 28, 2011, which is incorporated herein by reference in its entirety.

### BACKGROUND

1. Field

Exemplary embodiments of the present invention relate to a stack-type semiconductor device.

2. Description of the Related Art

Semiconductor devices may store and process large amount of data in a short amount of time. Also, semiconductor device may perform diverse functions. Semiconductor devices may include the above described features by stacking a plurality of chips that perform similar or different functions in one semiconductor package.

FIG. 1 illustrates a plurality of chips stacked on a wafer.

A semiconductor device may be fabricated by a Known Good Stack Die (KGSD) scheme. The KGSD scheme is where only chips that operate normally are stacked. According to the KGSD scheme, chips are stacked over chips that operate normally among a plurality of chips of a bottom wafer. The stacked chips are referred to as good dies or good chips. No chips are stacked over the chips that do not operate normally, which are referred to as failure dies or failure chips. In this way, unnecessary consumption of chips is prevented and production cost may be reduced.

FIG. 2, FIG. 3A, and FIG. 3B show a feature occurring when chips are not stacked over a failure chip.

Referring to FIG. 2, chips are stacked over good chips 201 and 203, and no chips are stacked over the failure chip 202. Consequently, there is a height difference between the stacks over the good chips 201 and 203 and the failure chip 202. The height difference makes it difficult to form the bottom wafer structure to a uniform height during molding, as shown in a portion denoted with 210 of FIG. 2. If the molding the bottom wafer structure is not uniform, testing may not be performed uniformly, which leads to a decreased yield. Also, non-uniform molding may cause an issue during a subsequent sawing process.

FIGS. 3A and 3B show the sawing process. Even if the mold structure has a uniform height as shown in FIG. 3A, when the mold structure goes through a sawing process in the direction of 301 and 302 of FIG. 3A, the mold structure is not sawn in the desired directions 301 and 302 due to cracks caused by the height difference between the stacked chips. As shown in FIG. 3B, the sawing is not performed correctly, as shown by the breaks 303 and 304, and the result of the sawing leads to a decreased yield.

### SUMMARY

An embodiment of the present invention is directed to a technology for preventing non-uniform molding or incorrect sawing that may occur due to height difference in a stack-type semiconductor device.

In accordance with an embodiment of the present invention, a semiconductor device includes: a wafer comprising a chip that passes a test and a chip that does not pass a test; one or more first stacked chips that are stacked over the chip that passes a test; and one or more second stacked chips that are stacked over the chip that does not pass a test, wherein the second stacked chips comprise at least one of another chip that does not pass a test and a dummy chip. In accordance with another embodiment of the present invention, a method for fabricating a semiconductor device includes: fabricating a wafer where a plurality of chips are mounted; stacking one or more first stacked chips that pass a test over each normally operating chip among the plurality of chips; and stacking one or more second stacked chips over each abnormally operating chip among the plurality of chips, wherein the second stacked chips comprise at least one of a chip that does not pass a test and a dummy chip.

### BRIEF DESCRIPTION OF THE DRAWINGS

FIG. 1 illustrates a plurality of chips stacked on a wafer.

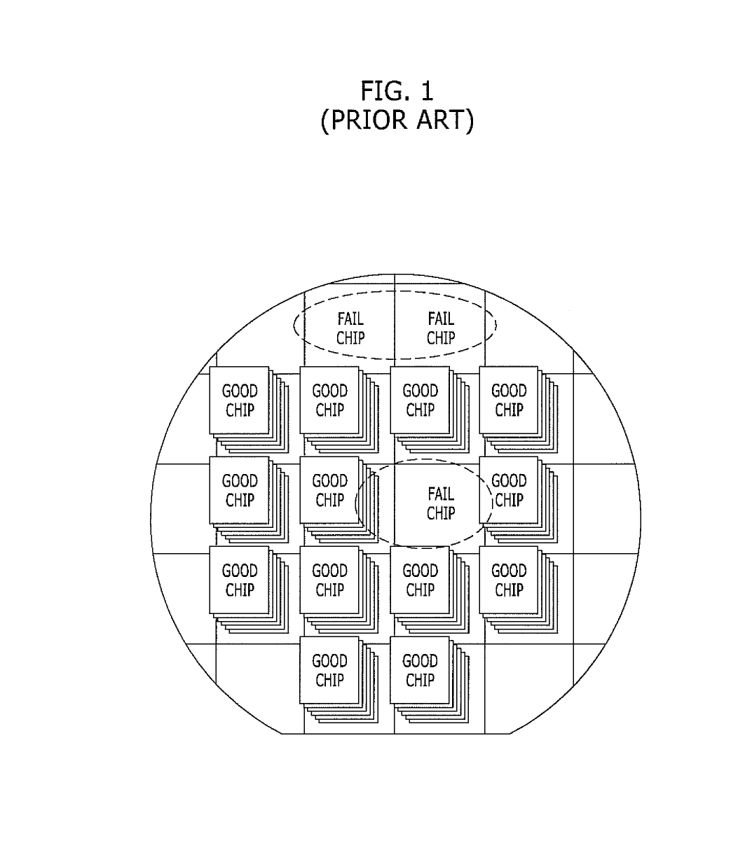

FIG. 2 and FIGS. 3A and 3B show a feature occurring when chips are not stacked over a failure chip.

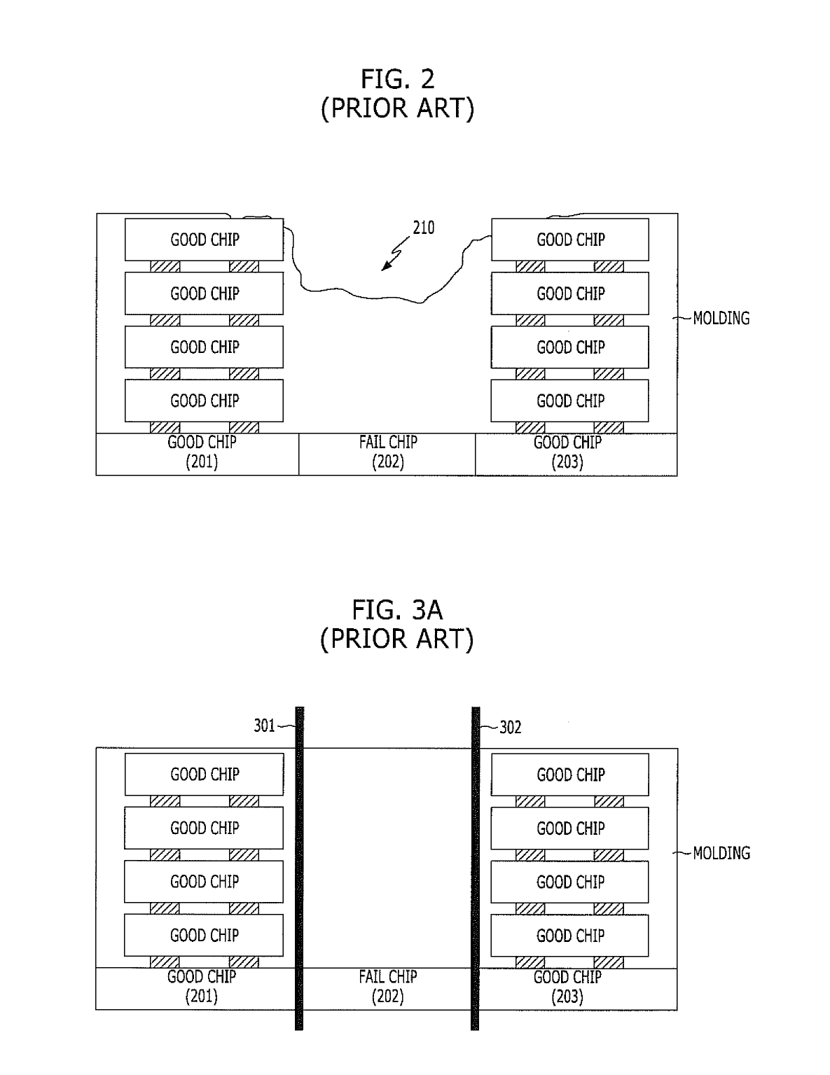

FIG. 4 illustrates a semiconductor device in accordance with an embodiment of the present invention.

FIGS. 5A and 5B illustrate a process of sawing the semiconductor device shown in FIG. 4.

FIG. 6 illustrates a top view of the semiconductor device of FIG. 4.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

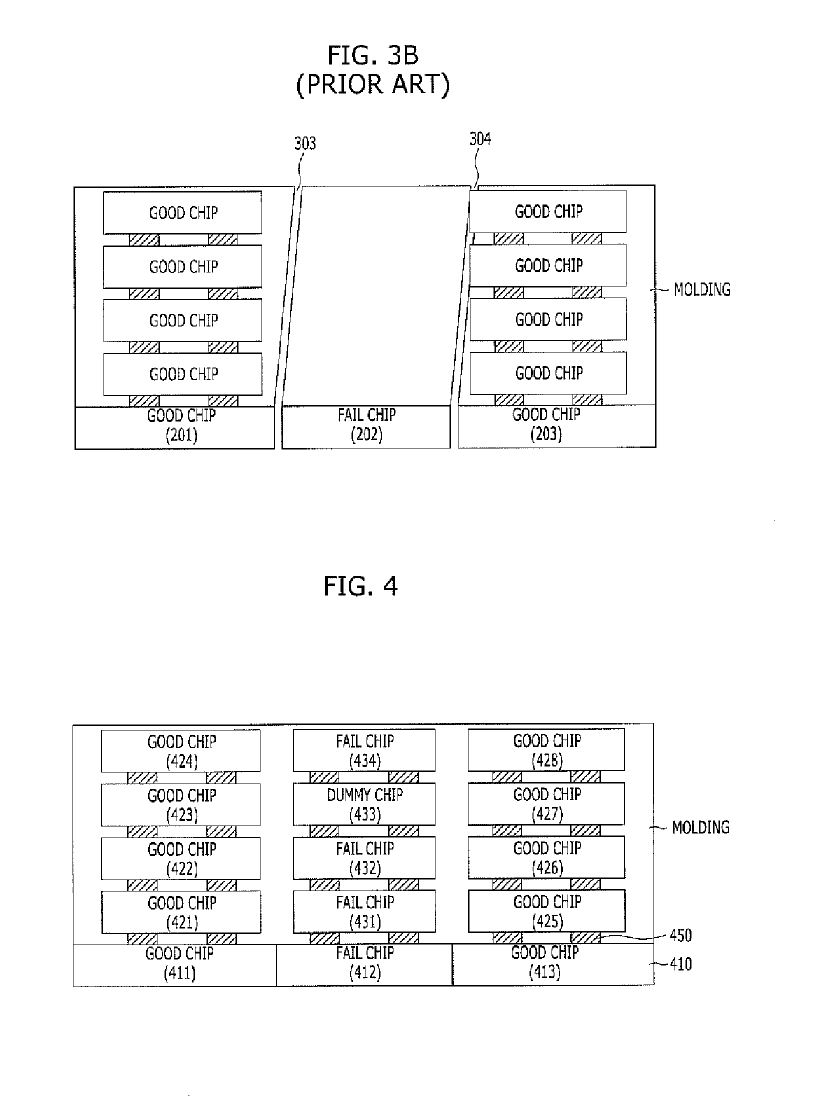

FIG. 4 illustrates a semiconductor device in accordance with an embodiment of the present invention.

Referring to FIG. 4, the semiconductor device includes a wafer 410 provided with normally operating chips 411 and 413 and an abnormally operating chip 412, one or more first stacked chips 421 to 428 that are stacked over the normally operating chips 411 and 413, and one or more second stacked chips 431 to 434 that are stacked over the abnormally operating chip 412.

Many chips may be disposed on one wafer, and some of the chips may abnormally operate. In FIG. 4, for illustration purposes, there are two normally operating chips 411 and 413 and one abnormally operating chip 412 on the bottom wafer 410. After a wafer is fabricated, normally operating chips and abnormally operating chips are identified through a test process.

The first stacked chips 421 to 428 are chips that are stacked over the normally operating chips 411 and 413 of the bottom wafer 410. The first stacked chips 421 to 428 are normally operating chips. The normally operating chip 411 and the first stacked chips 421 to 424 are to be mounted in the inside of one package, and the normally operating chip 413 and the first stacked chips 425 to 428 are to be mounted in the inside of another package. The chips are mounted in different packages because if there is any abnormally operating chip in a package, the package cannot normally operate.

The second stacked chips 431 to 434 are chips that are stacked over the abnormally operating chip 412 of the bottom wafer 410. Since the abnormally operating chip 412 cannot normally operate, it is wasteful to stack normally operating chips over the abnormally operating chip 412. Therefore, the abnormally operating chips 431, 432 and 434 or a dummy chip 433 are stacked as the second stacked chips 431 to 434. The abnormally operating chips 431, 432 and 434 are chips that are produced through a chip fabrication process but were identified as not normally operating chips as a result of a test. The dummy chip 433 is a chip that does not go through a normal fabrication process, and more specifically, the dummy chip 433 is a chip cut out of a wafer without performing a fabrication process. The second stacked chips 431 to 434 are stacked over the abnormally operating chip 412 to have a similar height as the stack of first stacked chips 421 to 428 on the normally operating chips 411 and 413. Therefore, the number of chips and the height of the stack over the abnormally operating chips should be the same as the number of chips and the height of the stack over the normally operating chips.

Interface channels 450 are formed between the stacked chips through which the stacked chips may transfer signals (or data). The interface channel 450 may be formed by implementing a bump or a Through Silicon Via (TSV).

The interface channel 450 is useful between the normally operating chips 411 and 413 and the of the bottom wafer 410. However, since the abnormally operating chip 412 and the second stacked chips 431 to 434 may not be used, an interface channel may not be formed between the second stacked chips 431 to 434. However, an interface channel may be formed between the abnormally operating chip 412 and the second stacked chips 431 to 434 to make the height of the second stacked chips 431 to 434 the same as the height of the first stacked chips 421 to 428.

The normally operating chips 411 and 413 formed on the bottom wafer 410 and the first stacked chips 421 to 428 that are stacked over the normally operating chips 411 and 413 may be chips of the same kind or different kinds. Generally, the normally operating chips 411 and 413 formed on the bottom wafer 410 are control chips for controlling the first stacked chips 421 to 428, and the first stacked chips 421 to 428 are the chips under the control of the control chips. For example, the normally operating chips 411 and 413 formed on the bottom wafer 410 may be chips including a memory controller, and the first stacked chips 421 to 428 may be memory chips.

According to an embodiment of the present invention, chips are stacked over both normally operating chips 411 and 413 and abnormally operating chip 412 of the bottom wafer 410. Thus, the height of the stacked chips stacked over the abnormally operating chip 412 may be the same as the height of the stacked chips stacked over the normally operating chips 411 and 413. Since the height of the stacked chips over the normally operating chips 411 and 413 and the stacked chips over the abnormally operating chip 412 may be the same, the semiconductor device may realize uniform molding. Also, since the heights of the stacked chips are uniform, a process of sawing semiconductor device can be accomplished more precisely. Therefore, the yield of a semiconductor device fabrication process may be improved. Moreover, since the chips stacked over an abnormally operating chip are abnormally operating chips or dummy chips, production cost may not increase.

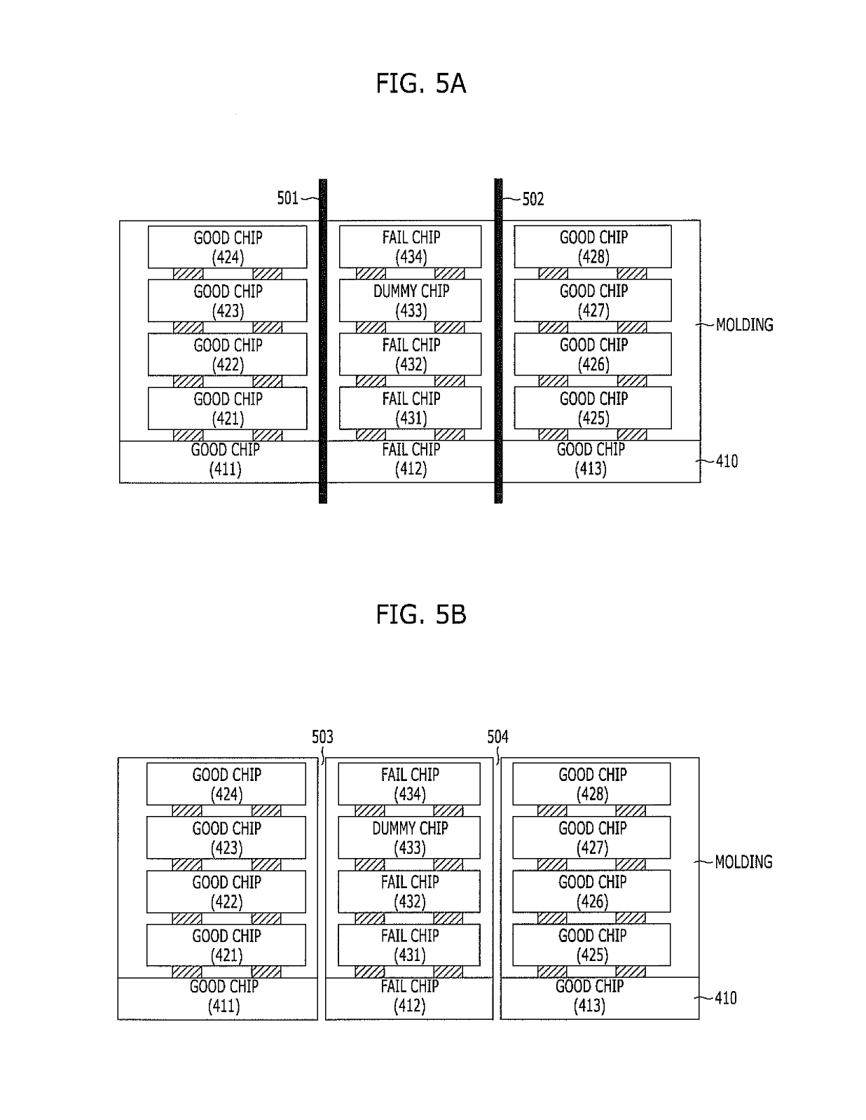

FIGS. 5A and 5B illustrate a process of sawing the semiconductor device shown in FIG. 4. FIGS. 5A and 5B illustrate that the target sawing direction 501 and 502 is in accord with a sawing result 503 and 504.

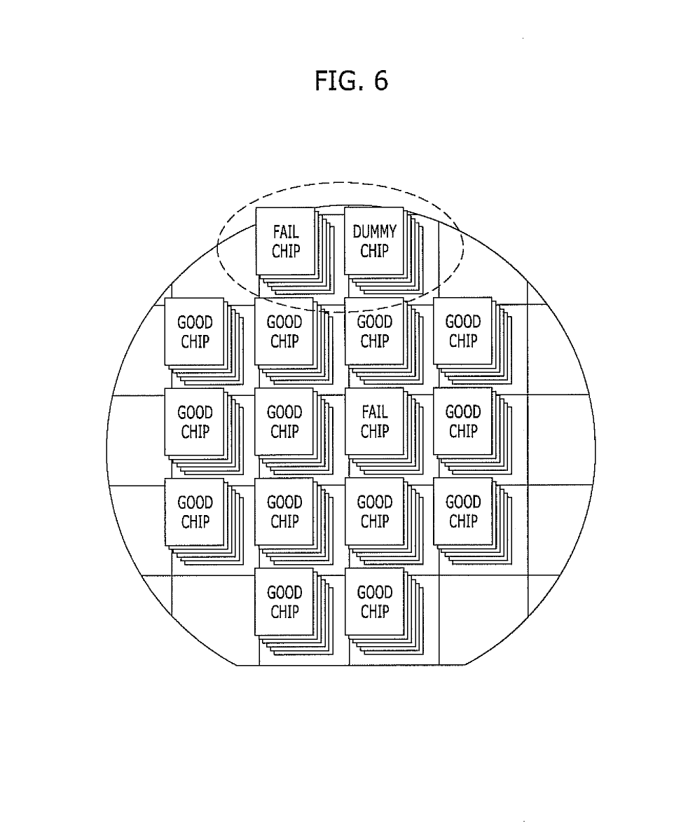

FIG. 6 illustrates the top view of the semiconductor device of FIG. 4. FIG. 6 illustrates that chips are stacked over the normally operating chips of the bottom wafer and over the abnormally operating chips as well.

Hereafter, a method for fabricating a semiconductor device in accordance with an embodiment of the present invention is described.

(1) First, a bottom wafer 410 where a plurality of chips is mounted is fabricated. When the fabrication of the bottom wafer 410 is completed, a test is performed to identify normally operating chips 411 and 413 and abnormally operating chips 412.

(2) First stacked chips 421 to 428, which are normally operating chips, are stacked over the normally operating chips 411 and 413 of the bottom wafer 410. Here, the first stacked chips 421 to 428 are not fabricated over the bottom wafer 410 but over another wafer, and subsequently identified as normally operating chips through another test process.

(3) Abnormally operating chip 431, 432 and 434 and/or a dummy chip 433 are stacked over an abnormally operating chip 412 of the bottom wafer 410. The abnormally operating chips 431, 432 and 434 are not fabricated over the bottom wafer 410 but over another wafer, and subsequently identified as abnormally operating chips through a test process. The dummy chip 433 is a chip cut out of a wafer without performing a fabrication process. The abnormally operating chips 431, 432 and 434 are chips to be abandoned, and no fabrication cost is invested to form the dummy chip 433. Therefore, the use of the abnormally operating chips 431, 432 and 434 and the dummy chip 433 does not bring about an increase in production cost.

(4) When all chips are stacked, a molding process is performed. After the molding process, a process of sawing the semiconductor device is performed. In FIG. 4, the normally operating chip 411 and the first stacked chips 421 to 424 are to be mounted onto one package, and the normally operating chip 413 and the first stacked chips 425 to 428 are to be mounted onto another package. After completing the sawing process, the chips are mounted into a package.

According to an embodiment of the prevent invention, chips are stacked over a chip that does not normally operate to the same height as a chip that normally operates. By stacking chips over the abnormally operating chip, the molding process may be uniform. Also, since the chips stacked over the abnormally operating chip of a bottom wafer are abnormally operating chips or dummy chips, the production cost may not increase.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a wafer comprising a chip that passes a test and a chip that does not pass a test;
one or more first stacked chips that are stacked over the chip that passes a test; and
one or more second stacked chips that are stacked over the chip that does not pass a test,
wherein the second stacked chips comprise at least one of another chip that does not pass a test and a dummy chip.

2. The semiconductor device of claim 1, wherein the number of the first stacked chips and the number of the second stacked chips are the same.

3. The semiconductor device of claim 1, wherein the first stacked chips and the second stacked chips are formed to have the same height.

4. The semiconductor device of claim 1, wherein the first stacked chips are chips that pass a test.

5. The semiconductor device of claim 1, wherein the chip that passes a test formed on the wafer and the first stacked chips interface with each other.

6. The semiconductor device of claim 5, wherein the chip that does not pass a test formed on the wafer and the second stacked chips have interface channels formed between the chip that does not pass a test and the second stacked chips and between the second stacked chips.

7. The semiconductor device of claim 1, wherein the chip that passes a test formed on the wafer is a control chip, and the first stacked chips are memory chips.

8. The semiconductor device of claim 1, wherein the wafer comprises the chip that passes a test and the chip that does not pass a test in plural, and
each of the chips that pass a test comprises the one or more first stacked chips stacked thereon, and
each of the chips that do not pass a test comprises the one or more second stacked chips stacked thereon.

9. A method for fabricating a semiconductor device, comprising:
fabricating a wafer where a plurality of chips are mounted;
stacking one or more first stacked chips that pass a test over each normally operating chip among the plurality of chips; and
stacking one or more second stacked chips over each abnormally operating chip among the plurality of chips,
wherein the second stacked chips comprise at least one of a chip that does not pass a test and a dummy chip.

10. The method of claim 9, wherein the number of the first stacked chips and the number of the second stacked chips are the same.

11. The method of claim 9, wherein the first stacked chips and the second stacked chips are formed to have the same height.

12. The method of claim 9, further comprising:
molding the wafer and the chips stacked over the wafer; and
sawing the wafer and the chips stacked over the wafer.

13. The method of claim 9, wherein the normally operating chip formed on the wafer is a control chip, and the first stacked chips are memory chips.
